(19) United States
(12) Patent Application Publication
(10) Pub. No.: US 2015/0044840 A1
(43) Pub. Date: Feb. 12, 2015

(54) METHOD FOR PRODUCING SILICON CARBIDE SEMICONDUCTOR DEVICE

(71) Applicants: Keisuke Kobayashi, Tokyo (JP); Toshiyuki Mine, Tokyo (JP); Hirotaka Hamamura, Tokyo (JP)

(72) Inventors: Keisuke Kobayashi, Tokyo (JP); Toshiyuki Mine, Tokyo (JP); Hirotaka Hamamura, Tokyo (JP)

(73) Assignee: Hitachi, Ltd., Chiyoda-ku, Toky0 (JP)

(21) Appl. No.: 14/381,597

(22) PCT Filed: Mar. 30, 2012
(86) PCT No.: PCT/JP2012/002223

§ 371 Date: Aug. 28, 2014

(51) Int. Cl. H01L 29/66; H01L 21/02; H01L 21/265; H01L 29/16

(52) U.S. Cl. CPC H01L 29/66477; H01L 29/1608; H01L 21/02252; H01L 21/0223; H01L 21/26513
USPC 438/285

(57) ABSTRACT

In order to provide a method for producing a SiC-MOSFET capable of increasing Vₜₕ without deteriorating channel mobility, before forming a gate insulation film, (a) silicon carbide substrate is oxidized by a low temperature oxidation method represented by plasma oxidation to form a silicon oxide film. Next, (b) the silicon oxide film is removed. After repeating the processes (a) and (b) once or more, (c) the gate insulation film is formed.

### TECHNICAL FIELD

The present invention relates to a sacrificial oxidation film used in a method for producing a silicon carbide semiconductor device.

### BACKGROUND ART

A general method for producing a SiC-MOSFET will be hereinafter described. First, a SiC epitaxial layer is formed on a SiC substrate. Then, ion implantation of an impurity, which is to be a dopant, is carried out with respect to a drain region, a base region, and a source region. Next, activation annealing is carried out with respect to the ion-implanted impurity. In a case of annealing, for example, a carbon film with excellent heat resistance is deposited as a cap material so that Si in the SiC substrate is not sublimed. Then, the carbon film is treated with heat treatment at temperature of 1600° C. or more. After that, a carbon layer of the cap material is removed by oxygen plasma asking or by heat treatment under oxygen atmosphere, for example, at around 900° C. in which the SiC substrate is hardly oxidized. However, because of reaction between the cap material and the substrate, a carbon compound to be formed cannot be completely removed. The carbon compound becomes a factor of degrading reliability of a gate insulation film. Therefore, the following method is generally used to remove the reacted carbon compound. Herein, thermal oxidation is carried out at high temperature with respect to an interface on which the gate insulation film is formed. Then, a silicon oxide film (sacrificial oxidation film) is formed, followed by removing the silicon oxide film with diluted hydrofluoric acid. This process is so-called sacrificial oxidation. Then, after undergoing a gate insulation film process, a silicide electrode process, and an interlayer insulation film forming process, the SiC-MOSFET is completely produced.

Most of the SiC-MOSFET formed in such a way has low Vₜₕ, and is of normally-on type. However, threshold voltage (Vₜₕ) of the existing Si-IGBT is about 5 to 5.5 V. In order to replace the threshold voltage with that of the SiC-MOSFET, threshold voltage (Vₜₕ) of 5 V or more is required. An example of a method to increase the Vₜₕ includes, for example, one that thickens dopant concentration of a base region on which a channel is formed.

On the other hand, in order to achieve a low-loss device, it is important to improve mobility, and to decrease on-resistance. However, in the existing SiC-MOSFET, a plurality of interface states exists on the silicon oxide film/a so-called silicon carbide MOS interface. Therefore, channel mobility decreases. Accordingly, it is necessary to improve MOS interface property and to increase the channel mobility. An example of a method to increase the channel mobility includes, for example, one that applies a deposited oxide film to a gate oxide film, and to carry out oxynitride treatment (NPL 1).

### CITATION LIST

### Non Patent Literature

NPL 1: M. Noborio, J. Suda, S. Beljakowa, M. Krieger, and T. Kimoto, phys. stat. sol. (a) 206, 2374 (2009)

### SUMMARY OF INVENTION

### Technical Problem

However, in a case of increasing Vₜₕ or channel mobility in the above-mentioned way, there is a technical problem hereinafter described.

In a method for thickening dopant concentration of a base region on which channel is formed, in order to increase the Vₜₕ, the Vₜₕ increases but the channel mobility decreases due to influence by high impurity concentration.

In a method for carrying out oxynitride treatment while applying a deposited oxide film to a gate oxide film in order to improve the channel mobility, the channel mobility improves but the Vₜₕ decreases.

An object of the present invention is to provide a SiC-MOSFET having both high channel mobility and high Vₜₕ.

### Solution to Problem

The present inventors have studied various sacrificial oxidation processes before forming a gate insulation film. As a result, the present inventors have found that Vₜₕ increases by carrying out plasma oxidation instead of thermal oxidation at high temperature. In other words, by using the plasma oxidation instead of the thermal oxidation in the related art for the sacrificial oxidation, Vₜₕ of 5 V or more can be obtained without deteriorating channel mobility of a SiC-MOSFET.

Among the inventions disclosed herein, a representative invention will be briefly described hereinafter.

That is, in a method for producing a semiconductor device according to the present invention, before forming a gate insulation film, (a) a silicon carbide substrate is oxidized by a low temperature oxidation method represented by the plasma oxidation to form a silicon oxide film. Next, (b) the silicon oxide film is removed. After repeating the processes (a) and (b) once or more, (c) the gate insulation film is formed.

### Advantageous Effects of Invention

According to the present invention, there is provided a SiC-MOSFET having both high channel mobility and high Vₜₕ.

### BRIEF DESCRIPTION OF DRAWINGS

FIG. 1 is a cross-sectional view of a silicon carbide semiconductor device in Example 1.

FIG. 2(a) is a cross-sectional view showing a part of a producing process of the silicon carbide semiconductor device in Example 1.

FIG. 2(b) is a cross-sectional view showing a part of the producing process of the silicon carbide semiconductor device in Example 1.

FIG. 2(c) is a cross-sectional view showing a part of the producing process of the silicon carbide semiconductor device in Example 1.

FIG. 2(d) is a cross-sectional view showing a part of the producing process of the silicon carbide semiconductor device in Example 1.

FIG. 2(e) is a cross-sectional view showing a part of the producing process of the silicon carbide semiconductor device in Example 1.

FIG. 2(f) is a cross-sectional view showing a part of the producing process of the silicon carbide semiconductor device in Example 1.

FIG. 2(g) is a cross-sectional view showing a part of the producing process of the silicon carbide semiconductor device in Example 1.

FIG. 2(h) is a cross-sectional view showing a part of the producing process of the silicon carbide semiconductor device in Example 1.

FIG. 2(i) is a cross-sectional view showing a part of the producing process of the silicon carbide semiconductor device in Example 1.

FIG. 2(j) is a cross-sectional view showing a part of the producing process of the silicon carbide semiconductor device in Example 1.

FIG. 2(k) is a cross-sectional view showing a part of the producing process of the silicon carbide semiconductor device in Example 1.

FIG. 3 is a view showing gate voltage dependency of drain current of the silicon carbide semiconductor device in Example 1, together with a comparative example.

FIG. 4 is a view showing gate voltage dependency of channel mobility of the silicon carbide semiconductor device in Example 1, together with a comparative example.

FIG. 5 is a table showing a relation between a peak value of the channel mobility and gate threshold voltage of the silicon carbide semiconductor device in Example 1, together with a comparative example.

FIG. 6 is a cross-sectional view of a silicon carbide semiconductor device in Example 2.

FIG. 7(a) is a cross-sectional view showing a part of a producing process of the silicon carbide semiconductor device in Example 2.

FIG. 7(b) is a cross-sectional view showing a part of the producing process of the silicon carbide semiconductor device in Example 2.

FIG. 7(c) is a cross-sectional view showing a part of the producing process of the silicon carbide semiconductor device in Example 2.

FIG. 7(d) is a cross-sectional view showing a part of the producing process of the silicon carbide semiconductor device in Example 2.

FIG. 7(e) is a cross-sectional view showing a part of the producing process of the silicon carbide semiconductor device in Example 2.

FIG. 7(f) is a cross-sectional view showing a part of the producing process of the silicon carbide semiconductor device in Example 2.

FIG. 7(g) is a cross-sectional view showing a part of the producing process of the silicon carbide semiconductor device in Example 2.

FIG. 7(h) is a cross-sectional view showing a part of the producing process of the silicon carbide semiconductor device in Example 2.

FIG. 7(i) is a cross-sectional view showing a part of the producing process of the silicon carbide semiconductor device in Example 2.

FIG. 7(j) is a cross-sectional view showing a part of the producing process of the silicon carbide semiconductor device in Example 2.

### DESCRIPTION OF EMBODIMENTS

Hereinafter, Examples of the present invention will be described in detail with reference to the accompanying drawings.

Note that in all the drawings for explaining Examples, the same members will be denoted with the same reference numerals and duplicative explanation will be omitted. Especially, regarding members having similar functions between different Examples, those members will be denoted with the same reference numerals even though they are different in shape, impurity concentration, crystallinity, and the like.

Hereinafter, the following process will be referred to as “sacrificial oxidation”. Herein, an interface on which a gate insulation film is formed is oxidized to form a silicon oxide film. Then, the silicon oxide film is removed with diluted hydrofluoric acid. The above-mentioned treatment is repeated once or more.

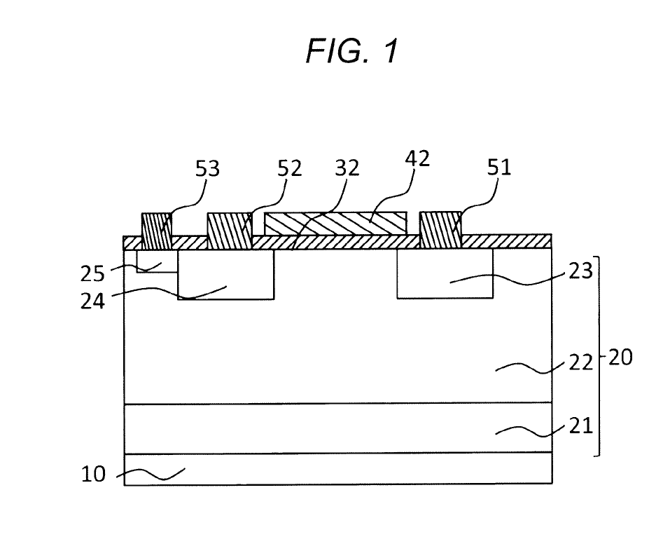

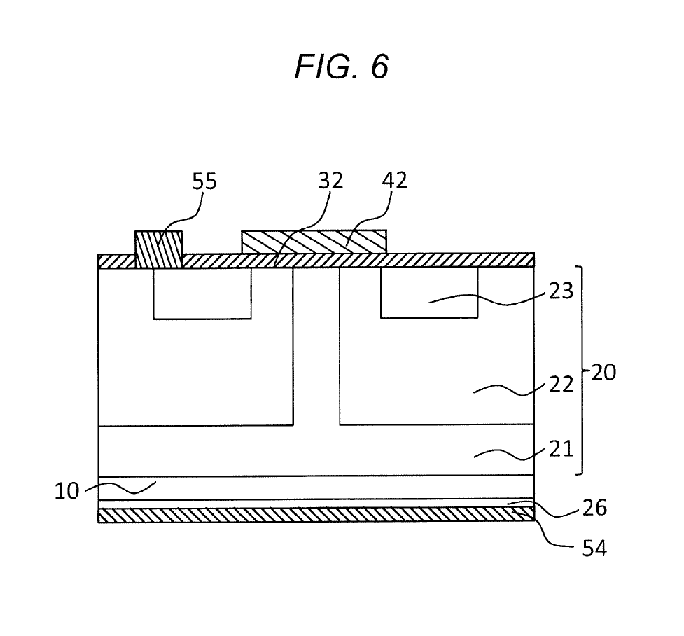

In Examples 1 and 2, silicon carbide semiconductor devices having a so-called metal-oxide-semiconductor (MOS) configuration shown in FIGS. 1 and 6 will be described.

Applicable examples of the semiconductor device having the MOS configuration are shown in FIGS. 1 and 6. FIG. 1 shows a configuration in which a source 23 and a drain 24 are disposed in a direction parallel to a substrate surface (hereinafter referred to as a horizontal MOS configuration). On the other hand, FIG. 6 shows a configuration in which a source 23 and a drain 26 are disposed in a direction vertical to a substrate surface (hereinafter referred to as a vertical MOS configuration).

### Example 1

### Horizontal MOS Configuration

In FIG. 1, a silicon carbide MOSFET, that is, a silicon carbide semiconductor device, includes a silicon carbide substrate 10, a silicon carbide layer 20, an insulation film 32, a gate electrode 42, a source electrode 51, a drain electrode 52, and abase contact electrode 53. The silicon carbide layer is formed on the silicon carbide substrate 10. The insulation film 32 is formed on the silicon carbide layer 20. The gate electrode is formed on the insulation film 32. The source electrode 51, the drain electrode 52, and the base contact electrode 53 are formed on the silicon carbide layer 20.

The silicon carbide layer 20 includes a silicon carbide epitaxial layer 21, a base region 22, a source region 23, a drain region 24, and a base contact region 25. The base region 22 is an ion-implanted region or an epitaxial layer. The source region 23, the drain region 24, and the base contact region 25 are ion-implanted regions.

Herein, as an impurity implanted into a region to be of n-type, for example, nitrogen (N) ion is used. On the other hand, as an impurity implanted into a region to be of p-type, for example, boron (B) or aluminum (Al) ion is used. In FIG. 1(a), an n⁺ region which is to be the source region 23 and the drain region 24 of the transistor and a p⁺ region which is to be the base contact region 25 is formed inside the p-type base region 22.

The gate insulation film 32, the source electrode 51, the drain electrode 52, and the base contact electrode 53 are formed on a surface of the silicon carbide layer 20.

The source electrode 51, the drain electrode 52, and the base contact electrode 53 are respectively connected with the source region 23, the drain region 24, and the base contact region 25.

The gate electrode 42 is formed so as to cover a part of the source region 23 and a part of the drain region 24 by involving the gate insulation film 32 on the silicon carbide layer 20.

[Method for Producing Horizontal MOS Configuration]

Next, a method for producing the above-mentioned horizontal MOS configuration will be described.

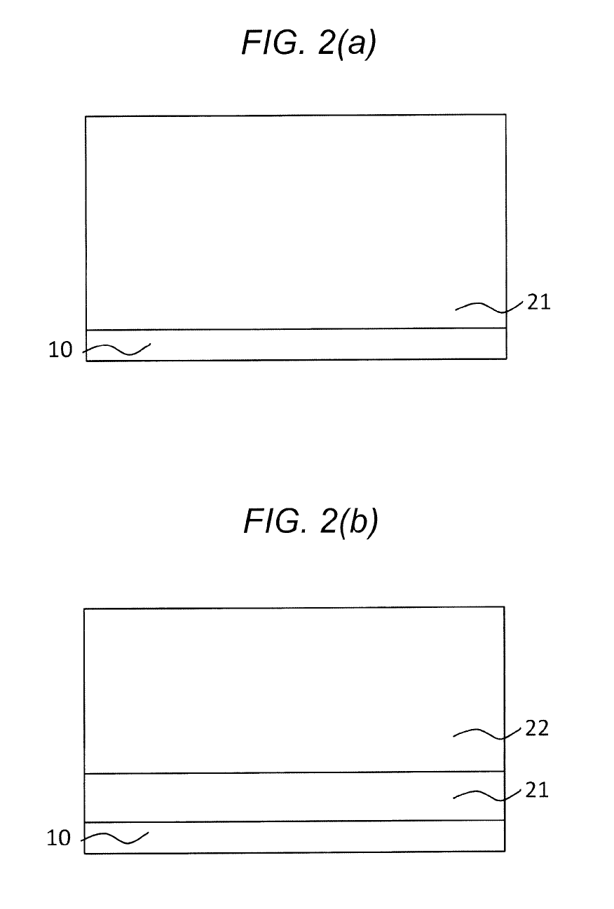

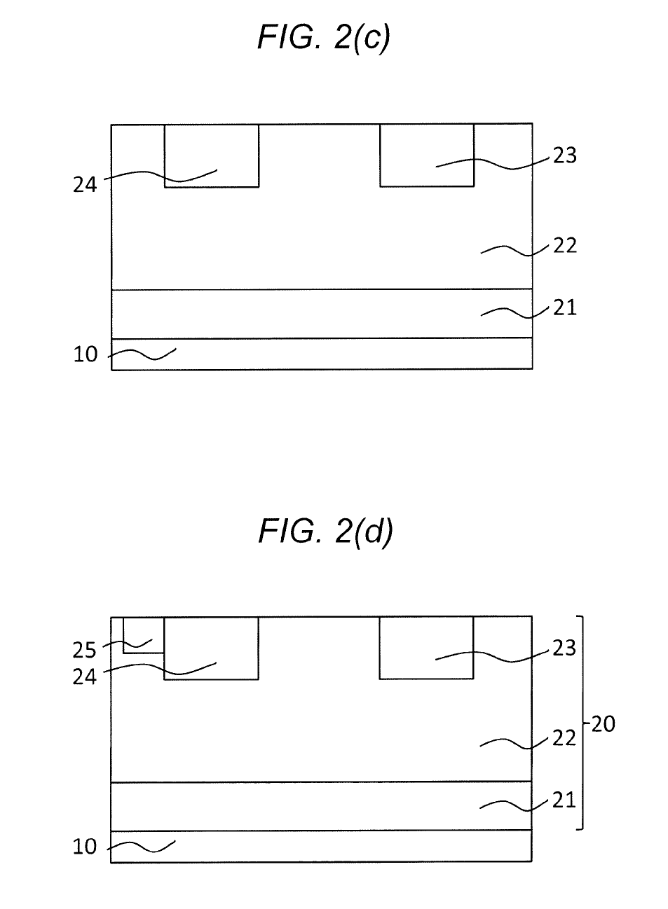

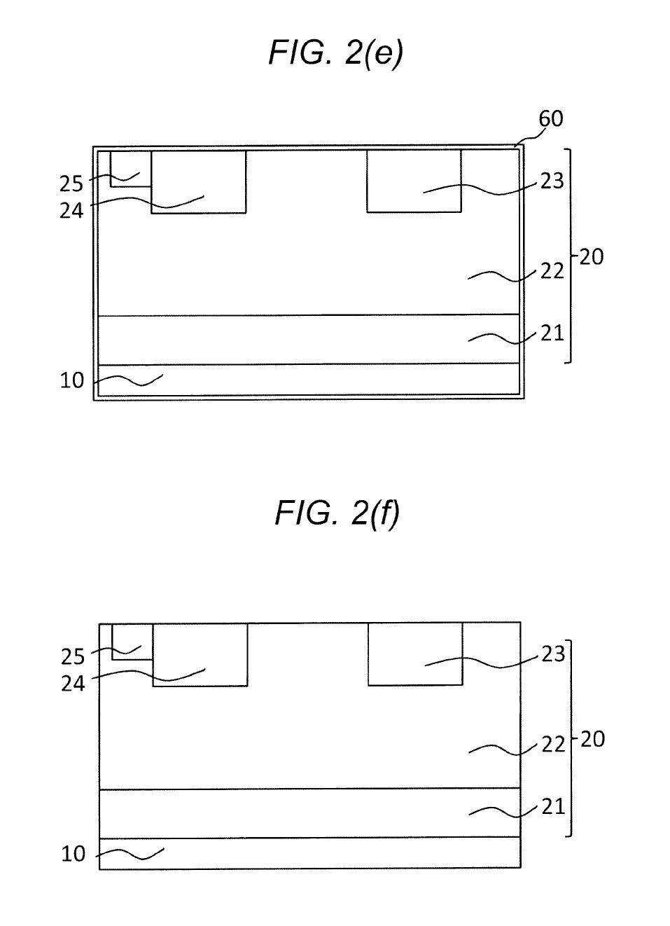

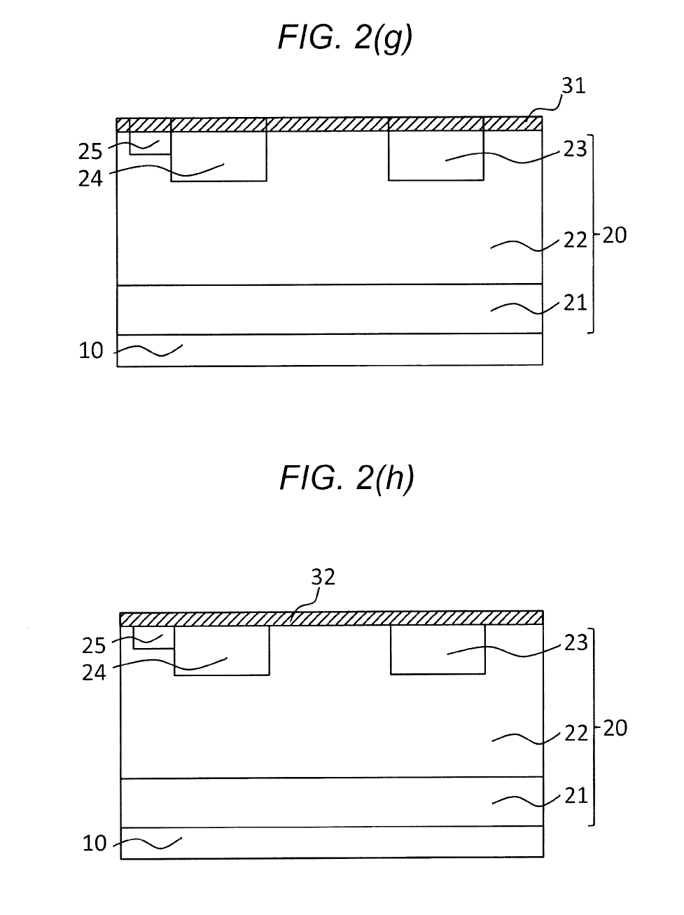

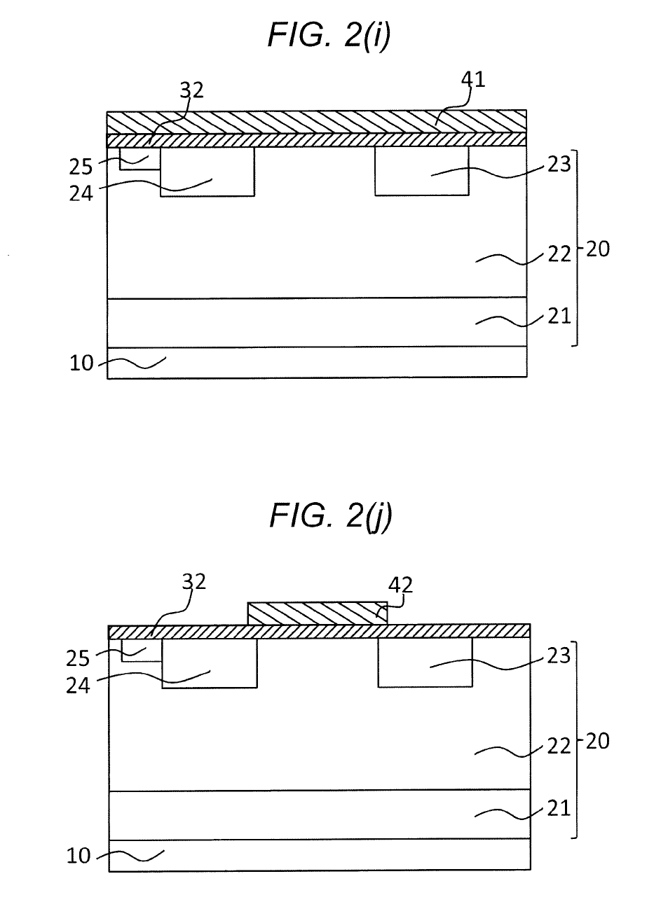

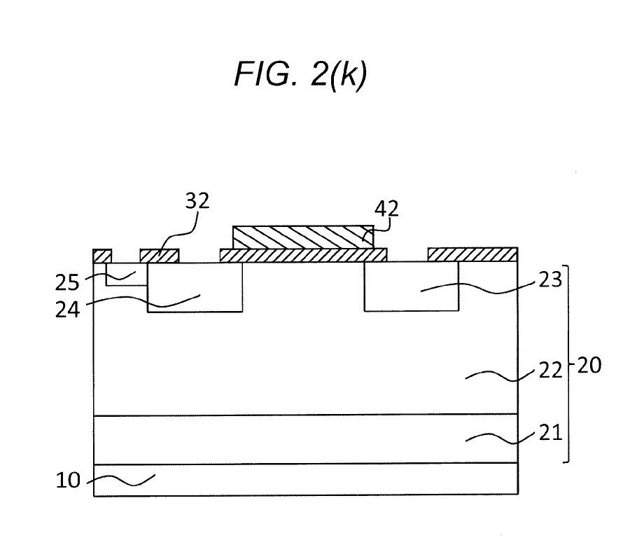

FIGS. 2(a) to 2(k) are cross-sectional views showing each of processes in producing a horizontal MOS transistor in Example 1. Note that these cross-sectional views only show configurations of main parts in the processes for fear that the drawings become complicated, and that they are not accurate cross-sectional views.

First, as shown in FIG. 2(a), the silicon carbide epitaxial layer 21 was laminated on the n-type silicon carbide substrate 10.

Next, as shown in FIG. 2(b), Al ion was implanted into a surface layer of the silicon carbide epitaxial layer 21 to form the p-type base region 22. Note that ion implanted into the base contact region 25 may be B ion. Moreover, a p-type silicon carbide epitaxial layer may be further formed on the silicon carbide epitaxial layer 21 to form the p-type base region 22.

Next, the source region 23 and the drain region 24 were masked for ion implantation. Then, N ion was implanted into the source region 23 and the drain region 24, as shown in FIG. 2(c). Then, the mask was removed.

Next, the base contact region 25 was masked for ion implantation. Then, Al ion was implanted into the base contact region 25, as shown in FIG. 2(d). Note that the ion implanted into the base contact region 25 may be B ion. Then, the mask was removed.

Next, as shown in FIG. 2(e), a carbon film 60 was deposited around the silicon carbide substrate 10 and the silicon carbide layer 20, as a cap material for impurity activation annealing. After that, the impurity activation annealing was carried out, for example, at temperature from 1600 to 1800° C. In the present Example, the impurity activation annealing was carried out at 1700° C. for 60 seconds.

Next, as shown in FIG. 2(f), a carbon layer of the cap material was removed by oxygen plasma asking. In this occasion, a carbon compound formed by reaction between carbon of the cap material and the substrate could not be completely removed. Therefore, the sacrificial oxidation using plasma oxidation was carried out. More specifically, after carrying out a predetermined cleansing, the plasma oxidation was carried out with respect to the surface of the silicon carbide layer 20 to form an oxidation film 31, as shown in FIG. 2(g). Then, the oxidation film 31 was removed by the diluted hydrofluoric acid. The above-mentioned process, a so-called sacrificial oxidation process, was repeated once or more. In the sacrificial oxidation process, when a removal thickness of the silicon carbide layer 20 is thin, the carbon compound cannot be completely removed. On the other hand, when the removal thickness thereof is thick, it affects impurity concentration of the ion-implanted region. Therefore, the removal thickness is preferably 3 nm to 30 nm. In the sacrificial oxidation process using the thermal oxidation in the related art, the source region 23, the drain region 24, the base contact region 25, which are ion-implanted regions, and the silicon carbide epitaxial layer 21 have different oxidation rate. Therefore, a step is generated in an interface between the silicon carbide layer 20 and a gate oxide film 32. This step causes degrading of device property such as electric field concentration with respect to the gate insulation film. In a method using the plasma oxidation of the present invention, it is possible to form an even interface with no steps, and to obtain excellent device property. In the present Example, plasma oxidation by an inductive coupled plasma (ICP) method was used at temperature of 500° C. or less in order to form the oxidation film 31. In the present Example, the above-mentioned process, so-called sacrificial oxidation, was repeatedly carried out. The thickness of the silicon carbide layer 20 removed by the sacrificial oxidation was formed to be, for example, 10 nm.

Next, as shown in FIG. 2(h), the gate oxide film 32 was formed on the semiconductor substrate. In the present Example, a deposited oxide film having the thickness of 50 nm was formed, and oxynitride treatment was carried out at 1300° C. for 30 minutes.

Next, as shown in FIG. 2(i), a gate material film 41 including an n-type polycrystalline silicon film having the thickness of 200 nm was deposited.

Next, as shown in FIG. 2(j), the gate material film 41 was etched with using a resist as a mask to form the gate electrode 42 of the MOS transistor.

Next, through-holes were formed on the gate material film located on the source region 23, the drain region 24, and the base contact region 25, as shown in FIG. 2(k). Then, contacts of the source electrode 51, the drain electrode 52, and the base contact electrode 53 were respectively formed on the source region 23, the drain region 24, and the base contact region 25. In addition to this process (including a silicidation process), a process of forming wires were carries out to complete the semiconductor device in FIG. 1.

[Device Evaluation of SiC-MOSFET]

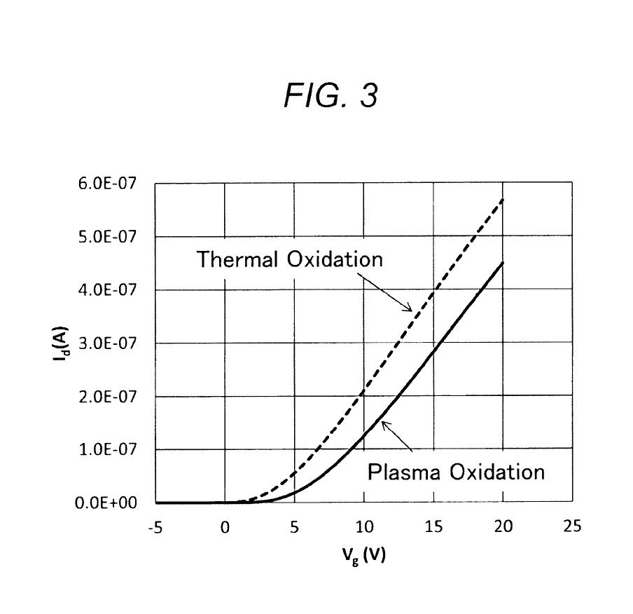

FIGS. 3 to 5 show device evaluation results of the SiC-MOSFET of specification in which the plasma oxidation has been used for the sacrificial oxidation (hereinafter abbreviated as plasma oxidation specification) and specification in which the thermal oxidation in the related art has been used for the sacrificial oxidation (hereinafter abbreviated as thermal oxidation specification).

FIG. 3 shows gate voltage dependency (I_{d}V_{g} property) of drain current of the silicon carbide semiconductor device in Example 1. “Thermal Oxidation” shows a property line in a case of using a thermal oxidation film, while “Plasma Oxidation” shows a property line in a case of using a plasma oxidation film. As shown in FIG. 3, Vₜₕ of the plasma oxidation specification became higher than that of the thermal oxidation specification. More specifically, in the thermal oxidation specification, Vₜₕ=4.3 V. On the other hand, in the plasma oxidation specification, Vₜₕ=6.6 V, which is about 2.3 V higher than the thermal oxidation specification.

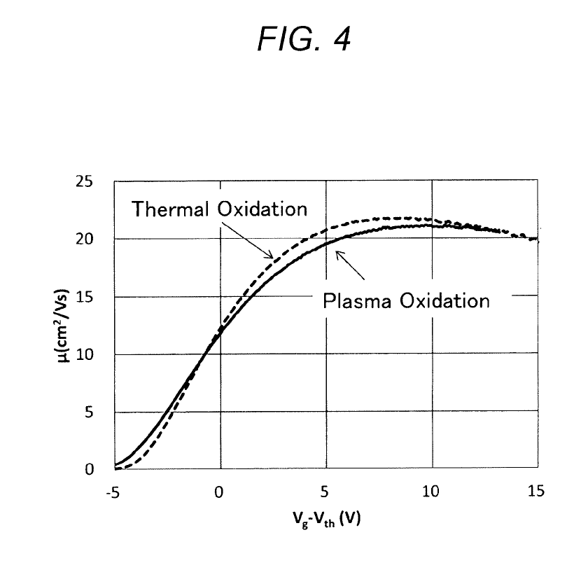

FIG. 4 shows gate voltage dependency of channel mobility μ of the silicon carbide semiconductor device in Example 1. “Thermal Oxidation” shows a property line in a case of using a thermal oxidation film, while “Plasma Oxidation” shows a property line in a case of using a plasma oxidation film. A value subtracting threshold voltage Vₜₕ from gate voltage Vg is taken along the abscissa in FIG. 4. Regarding the maximum value of the channel mobility, μ=21.8 cm2/V·s in the thermal oxidation specification, while μ=21.1 cm2/V·s in the plasma oxidation specification, as shown in FIG. 4. There is no great distinction between those two specifications.

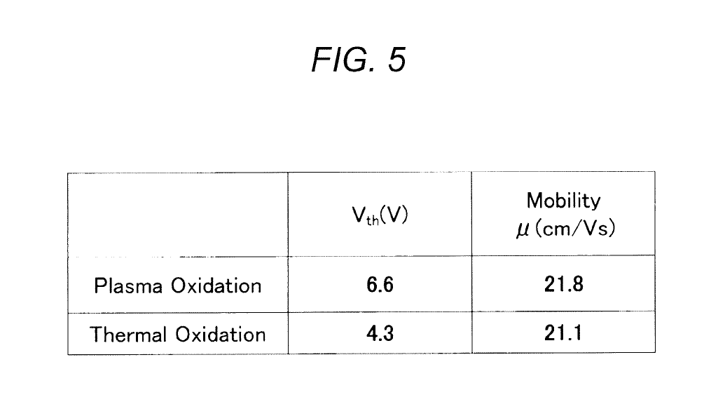

FIG. 5 shows a table summarizing values of the Vₜₕ and the channel mobility μ. “Thermal Oxidation” shows a data in a case of using the thermal oxidation film, while “Plasma Oxidation” shows a data in a case of using the plasma oxidation film. As seen from FIG. 5, the Vₜₕ in the plasma oxidation specification increased about 2.3 V with barely changing the channel mobility, compared to the thermal oxidation specification. As mentioned above, in the process of producing a normal MOS transistor, it is clear that it is possible to increase the Vₜₕ without changing the channel mobility of the SiC-MOSFET (with retaining the mobility comparable with that of the thermal oxidation film) by replacing a sacrificial oxidation film using the thermal oxidation in the related art with the plasma oxidation film.

In Example 1, the n-type silicon carbide monocrystalline semiconductor substrate was used. However, a p-type silicon carbide substrate may be used as well. In such a case, the MOS configuration can be formed by inverting polar character of the impurity ion implanted into each region for forming the MOS configuration.

### Example 2

Hereinafter, an application of a vertical MOS configuration shown in FIG. 6 will be described. Note that the same members as shown in Example 1 will not be described herein.

[Vertical MOS Configuration]

In FIG. 6, a silicon carbide MOSFET, that is, a silicon carbide semiconductor device, includes a silicon carbide substrate 10, a backside contact region 26, a drain electrode 54, a silicon carbide layer 20, an insulation film 32, a gate electrode 42, and a source base contact common electrode 55. The backside contact region 26 is an ion-implanted region formed inside the silicon carbide substrate 10. The drain electrode 54 is formed on the backside contact region 26. The silicon carbide layer 20 is formed on the silicon carbide substrate 10 together with the drain electrode 54. The insulation film 32 is formed on the silicon carbide layer 20. The gate electrode 42 is formed on the insulation film 32. The source base contact common electrode 55 is formed on the silicon carbide layer 20. The silicon carbide layer 20 includes a silicon carbide epitaxial layer 21, a base region 22 and a source region 23. The base region 22 and the source region 23 are ion-implanted regions.

Herein, as an impurity implanted into a region to be of n-type, for example, nitrogen (N) ion is used. On the other hand, as an impurity implanted into a region to be of p-type, for example, boron (B) or aluminum (Al) ion is used. For example, in the drawing, the p+ type backside contact region 26 is formed inside the silicon carbide substrate 10, and the n+ type source region 23 is formed as similar to Example 1.

The gate insulation film 32 and the source base contact common electrode 55 are formed on a surface of the silicon carbide layer 20. The drain electrode 54 is formed in the backside of the silicon carbide layer 20.

The source base contact common electrode 55 is connected with the base region 22 and the source region 23. The drain electrode 54 is connected with the backside contact region 26.

The gate electrode 40 is formed so as to cover a part of the n-type source region 23 by involving the gate insulation film 32 on the silicon carbide layer 20.

[Method for Producing Vertical MOS Configuration]

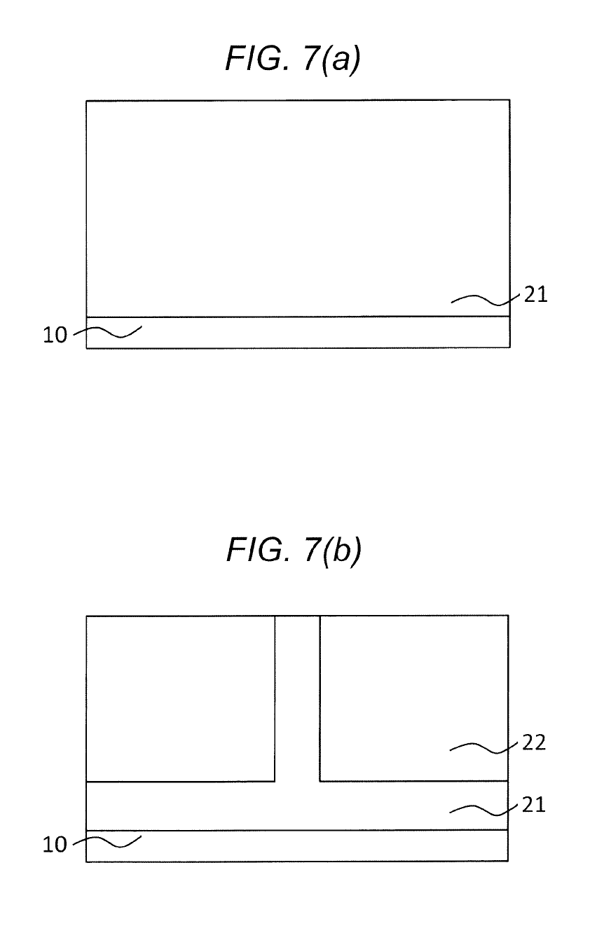

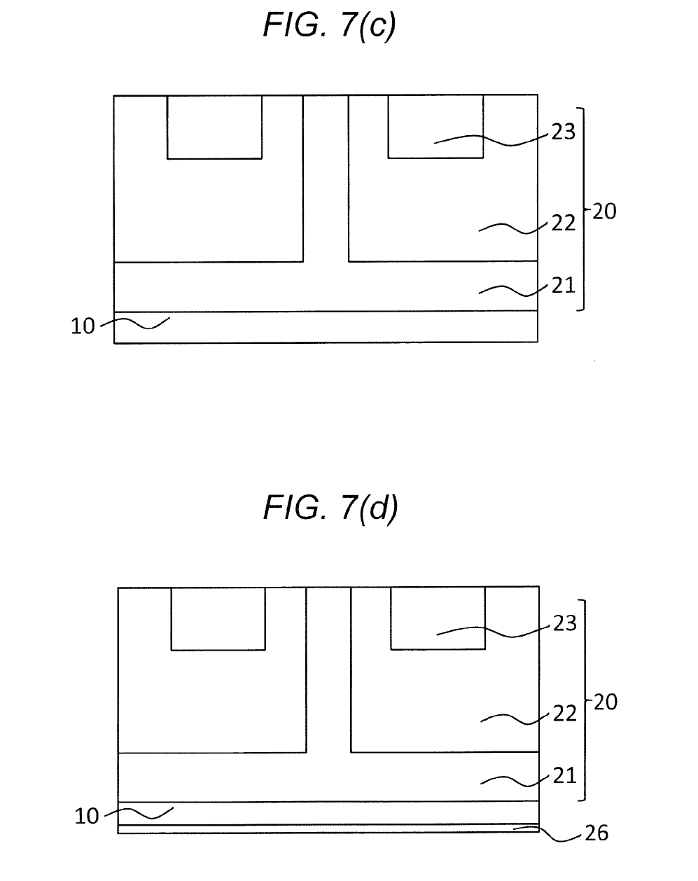

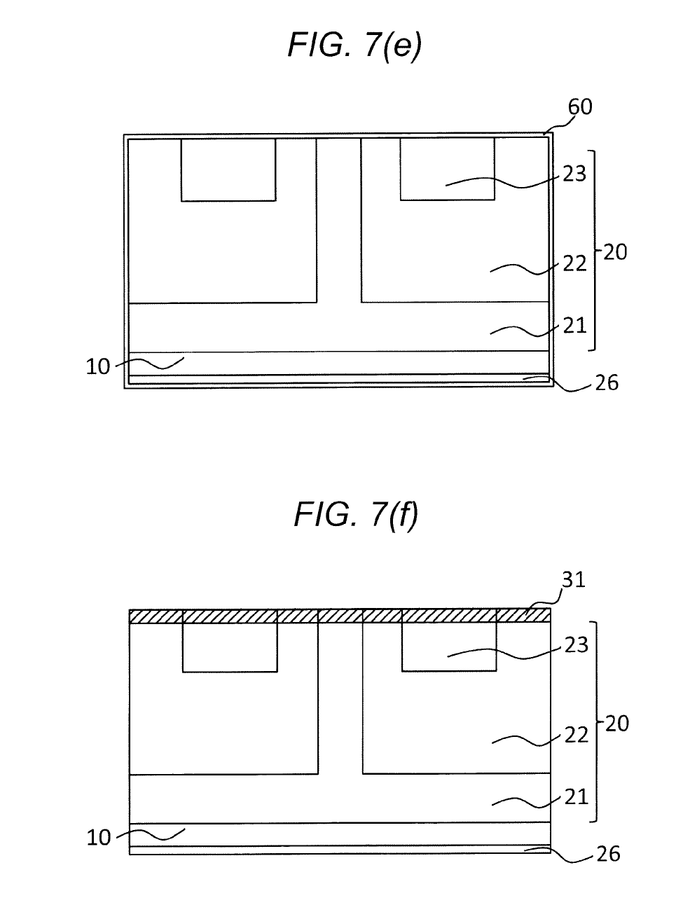

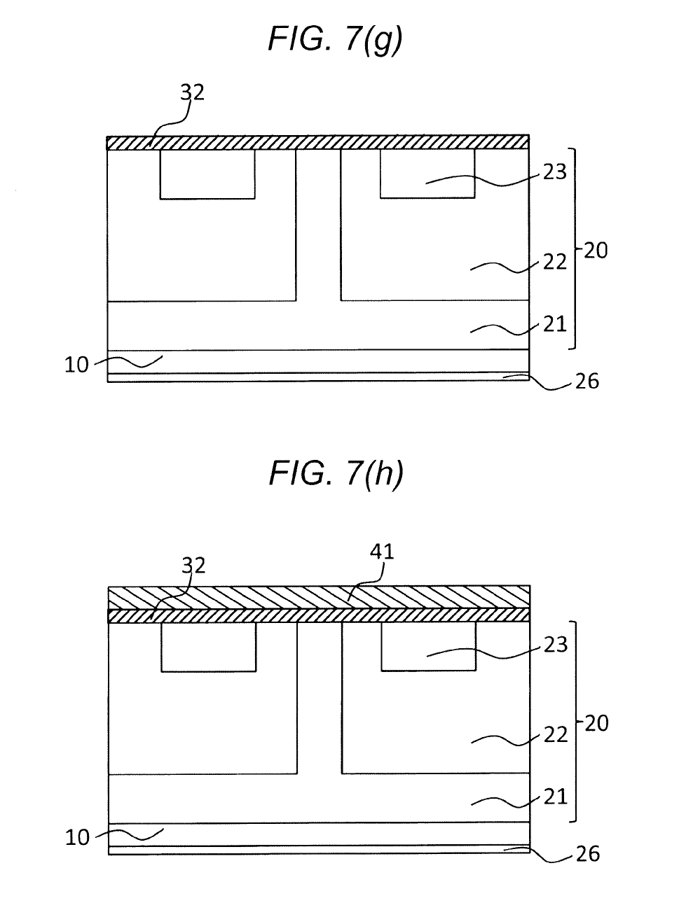

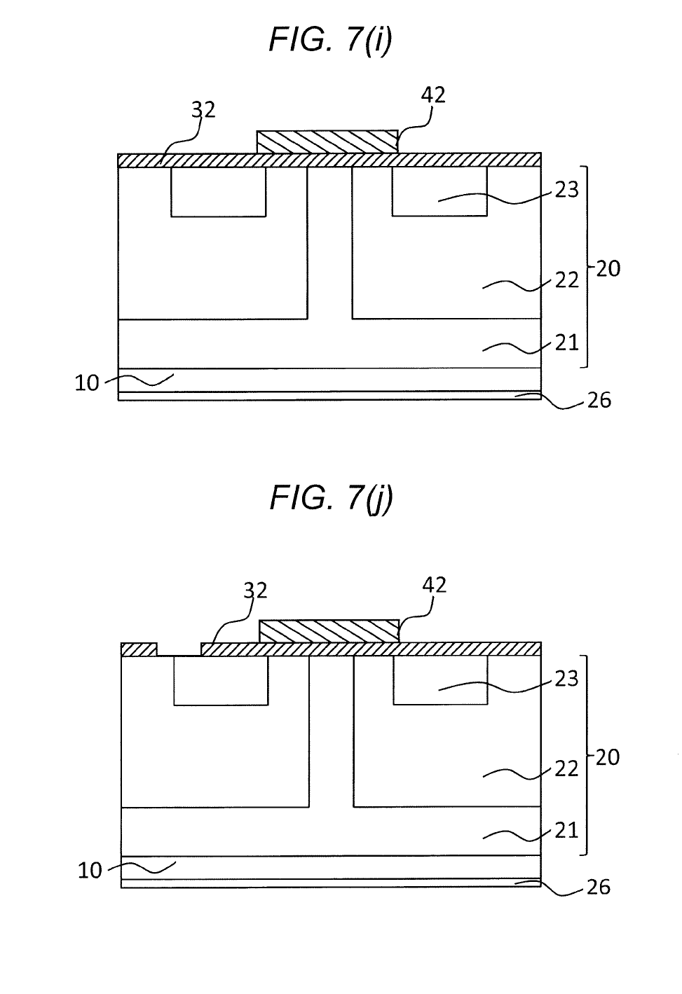

Next, a method for producing the above-mentioned vertical MOS configuration will be described. Note that a duplicative explanation for the same producing method as shown in Example 1 will not be described in detail. FIGS. 7(a) to 7(j) are cross-sectional views showing each of processes in producing a vertical MOS transistor in Example 2. Note that these cross-sectional views only show configurations of main parts in the processes for fear that the drawings become complicated, and that they are not accurate cross-sectional views.

First, the silicon carbide epitaxial layer 21 was laminated, as shown in FIG. 7(a).

Next, as shown in FIGS. 7(b), 7(c), and 7(d), ions were implanted into the p-type base region 22, the n-type source region 23, and the backside contact region 26. Further, regarding ion type used for implantation, Al ion was used for the backside contact region 26. On the other hand, similar types in Example 1 were used for implantation into the p-type base region 22 and the n-type source region 23. Note that the ion implanted into the backside contact region 26 maybe B ion.

Next, as shown in FIG. 7(e), a carbon film 60 was deposited on surfaces of the silicon carbide substrate 10 and the silicon carbide layer 20. After that, annealing for impurity activation was carried out at temperature, for example, from 1600 to 1800° C.

Next, a carbon layer of a cap material was removed by oxygen plasma ashing. In this occasion, a carbon compound formed by reaction between carbon of the cap material and the substrate could not be completely removed. Therefore, as shown in FIG. 7(f), sacrificial oxidation using plasma oxidation was carried out. More specifically, after carrying out a predetermined cleansing, the plasma oxidation was carried out with respect to the surface of the silicon carbide layer 20, to form an oxidation film 31. Then, the oxidation film 31 was removed by diluted hydrofluoric acid. Further, in a case of utilizing sacrificial oxidation using thermal oxidation, not only the surface but also the backside is oxidized at the same time. Therefore, in a case of carrying out ion implantation with respect to the backside contact region 26, ion implantation had to be carried out while considering a thickness to be removed by the sacrificial oxidation. In a case of utilizing the sacrificial oxidation using the above-mentioned plasma oxidation, the backside is hardly oxidized. Accordingly, in a case of carrying out ion implantation with respect to the backside contact region 26, there is no need to consider removal due to the sacrificial oxidation. It is enough to carry out ion implantation into a part closest to a backside surface with concentration in which the backside contact region 26 can come into contact with the electrode. Due to this effect, it becomes easy to be in good contact with the electrode.

Next, as shown in FIG. 7(g), agate oxide film 32 was formed on the semiconductor substrate. In the present Example, a deposited oxide film having the thickness of 50 nm was formed, and oxynitride treatment was carried out at 1300° C. for 30 minutes.

Next, as shown in FIGS. 7(h) and 7(i), the gate material film 41 was deposited, and the gate material film 41 was etched to form the gate electrode 42 of the MOS transistor.

Next, as shown in FIG. 7(j), a through-hole was formed on a boundary of the base region 22 and the source region 23. Then, contacts of the source base contact common electrode 55 and the drain electrode 54 were formed respectively on the boundary of the base region 22 and the source region 23, and on the backside contact region 26. In addition to this process (including silicidation process), a process of forming wires was carries out to completely form the semiconductor device in FIG. 6.

Similarly to Example 1, even in the configuration and the producing method in the present Example 2, it is possible to increase Vₜₕ, without changing mobility by changing only the method of forming the lower part of the gate insulation film in the MOS transistor having the vertical MOS configuration.

### REFERENCE SIGNS LIST

10 . . . silicon carbide substrate, 20 . . . silicon carbide layer, 21 . . . silicon carbide epitaxial layer, 22 . . . base region, 23 . . . source region, 24 . . . drain region, 25 . . . base contact region, 26 . . . backside contact region, 31 . . . sacrificial oxidation film, 32 . . . gate insulation film, 41 . . . gate material film, 42 . . . gate electrode, 51 . . . source electrode, 52 . . . drain electrode, 53 . . . base contact electrode, . . . drain electrode, 55 . . . source base contact common electrode, 60 . . . carbon film

1. A method for producing a silicon carbide semiconductor device including a gate oxide film formed on a silicon carbide layer, comprising:
a process for carrying out annealing after forming a cap material on the silicon carbide layer;
a process for forming a sacrificial oxidation film by an oxidation method at temperature lower than thermal oxidation temperature after removing the cap material; and
a process for forming the gate oxide film after removing the sacrificial oxidation film.

2. The method for producing the silicon carbide semiconductor device according to claim 1, wherein the cap material is a carbon film.

3. The method for producing the silicon carbide semiconductor device according to claim 2, comprising a process of implanting impurity ion before forming the cap material,
wherein the annealing is carried out at temperature in which the impurity ion is activated, or at temperature more than the temperature.

4. The method for producing the silicon carbide semiconductor device according to claim 3, wherein
the impurity ion is implanted such that impurity concentration of the source region differs from impurity concentration of the base region, and
a film thickness of the sacrificial oxidation film is 3 nm or more and 30 nm or less.

5. The method for producing the silicon carbide semiconductor device according to claim 2, wherein the sacrificial oxidation film is formed at 500° C. or less.

6. The method for producing the silicon carbide semiconductor device according to claim 5, wherein the sacrificial oxidation film is formed by plasma oxidation.
